(19) United States
(12) Patent Application Publication
(10) Pub. No.: US 2004/0156320 A1
(43) Pub. Date: Aug. 12, 2004

(54) Method for operating a network with wireless transmission of data and subscriber for said network

(75) Inventors: Gerhard Hammer, Neupotz (DE); Klaus Roether, Stutensee (DE)

Correspondence Address: SUGHRUE MION, PLLC, 2100 PENNSYLVANIA AVENUE, N.W., SUITE 800, WASHINGTON, DC, 20037, US

(73) Assignee: SIEMENS AKTIENGESELLSCHAFT

(21) Appl. No.: 10/717,563

(22) Filed: Nov. 21, 2003

Related U.S. Application Data
(63) Continuation of application No. PCT/DE02/01849, filed on May 22, 2002.

(30) Foreign Application Priority Data
May 23, 2001 (DE) 101 253 87.7

(51) Int. Cl. G01R 31/08

(52) U.S. Cl. 370/252

(57) ABSTRACT

A method and device for operating a network with wireless transmission of data among a plurality of users. The network includes at least two radio cells. Test cycles of a given maximum duration are processed by the base stations at given maximum intervals in time. Test signals within the test cycles are transmitted to the respective radio cells by the base stations and are used by radio-coupled users to determine the communication channel with the best transmission properties.

This is a Continuation of International Application PCT/DE02/01849, with an international filing date of May 22, 2002, which was published under PCT Article 21(2) in German, and the disclosure of which is incorporated into this application by reference.

### FIELD AND BACKGROUND OF THE INVENTION

The invention disclosed herein generally relates to a method for operating a network with wireless data transmission and a user for such a network. More specifically, the invention relates to an improved method, and a system for implementing the method, for the handoff of a mobile wireless communication device traveling between various cells in a communication network.

U.S. Pat. No. 6,088,591 discloses a network with wireless data transmission between a plurality of users that may be at fixed locations but are also capable of roaming within the network. The network has a plurality of radio cells, each of which has at least one base station for wireless data communication with the users located within the cell. To prevent the radio signals in neighboring cells, which partly overlap, from mutually interfering, different channels are used for wireless data transmission at least in neighboring cells. Possible ways to separate the different communication channels are, for example, Frequency Hopping Spread Spectrum (FHSS), Code Division Multiple Access (CDMA), Frequency Division Multiple Access (FDMA) and Time Division Multiple Access (TDMA). The base stations of different radio cells are interconnected via a common communication channel. This communication channel can be implemented, for example, by a bus with wire-bound data transmission or by a radio link.

When a radio-coupled user roams from one radio cell to an adjacent cell, a handoff procedure from one cell to another is required. The mobile users evaluate the signal quality and, depending on the result of this evaluation, switch communication channels in order to use the communication channel with the best transmission properties for communication with a base station. To minimize the delay involved in switching a mobile user to a new channel, the aforementioned patent proposes that neighboring base stations exchange various information via the common communication channel by which they are connected with one another. One piece of this information is the identification of the communication channel used within the respective cell. This information is also transmitted to the radio-coupled users within the cell. Thus, the users know which communication channels are used in neighboring cells, and they need to evaluate only those communication channels for the quality of their transmission properties. In addition, the mobile users located within the cell of a base station are managed by that base station, such that messages sent via the network can be routed by the corresponding base station to the users located within the associated cell, i.e., forwarded as a function of the destination address contained in the corresponding message.

A disadvantage of the prior art network is that it requires organizational data to be exchanged among the base stations in addition to the actual user data. Since the base stations and the radio-coupled users have to know the structure of the network, it may be necessary, in addition, to adapt the configuration or register newly connected users when structural changes are made. This increases the complexity involved in implementing the network. For example, the address tables of the mobile users reachable via the base station, which are stored in the base station to route the messages, have to be updated.

### OBJECTS OF THE INVENTION

One object of the present invention is to provide a method for efficiently operating a network with wireless data transmission among a plurality of users while enabling rapid roaming between different radio cells with little risk of losing data.

To attain this and other objects, one embodiment of the novel method of the initially described type includes providing each radio cell with at least one base station and interconnecting the base stations of different radio cells, respectively, via at least one common communication channel. The common communication channel can be, for example, a PROFIBUS communication link. Additionally, at predefined maximum time intervals and within the base stations, test cycles of a given maximum duration are processed and test signals are transmitted from the base stations to the respective radio cells during the test cycles. Within each respective radio-coupled user and based on the test signals, the communication channel with optimum transmission properties for that radio-coupled user is determined and the user is tuned to the particular channel with those properties.

Further, a novel user device is proposed which is operable to communicate with various base stations within a communication network, wherein the user device is configured to determine a communication channel with the best transmission properties based on test signals transmitted simultaneously by each of the base stations during test cycles and wherein further, the base stations process received data simultaneously at predefined maximum time intervals having a given maximum duration.

Also, a communication system that includes the method and user device includes a communication link operable to carry communication signals and a plurality of base stations each of which corresponds to a respective cell and each base station is also connected to the communication link, via, for example, a PROFIBUS link. Each base station is operable to transmit test signals in each of a plurality of different channels and a plurality of the user devices are operable to receive the test signals in each of the channels from each respective base station.

The invention has an advantage in that it eliminates time-consuming log-on and log-off procedures when mobile users roam into a different cell. The individual base stations do not need to keep any kind of list of the users that are logged-on in the respective cell. As a result, data traffic to update the lists on the communication channel for connecting base stations is also eliminated. The new method has the further advantage that it can be readily used in a network with a deterministic access method, e.g., based on the master-slave principle. Because it is not necessary to go through a lengthy handoff process with time-consuming log-on or log-off procedures, all the users can be reached at any time outside the test cycles. This reduces the risk of data loss. The method is therefore suitable for networks intended for time-critical applications, e.g., a field bus based on the PROFIBUS standard, which can be used to network sensors and actuators in a process control system. In a PROFIBUS DP field bus with cyclic data traffic, the test cycles can be integrated into the sequence of a cycle.

A further advantage is that the method can be easily adapted to the timing requirements of the corresponding application by suitably determining the predefined maximum time intervals between test cycles. For example, the time intervals between test cycles can be selected larger if the radio-coupled users move only slowly and stay for a relatively long time within the overlap area between two neighboring cells.

The method requires that the base stations located in the network execute the test cycles simultaneously. In a network in which the base stations have time synchronization, the instants for the respective start of the test cycles can be simply derived from the clock time using the predefined time intervals. Configuring a user as a so-called mobility master, which initiates the test cycles with messages recurring at the predefined intervals has the advantage, however, that an existing field bus can be readily expanded by this type of synchronization and that the test cycles can be easily initiated in a manner compatible with the cyclic data transmission of the field bus. Furthermore, inaccuracies in time synchronization do not interfere with the process.

Advantageously, the mobility master is the user having logic mastership in an access mode based on the master-slave principle. This has the advantage that the method is even simpler to implement because the initiation of the test cycles by recurrent messages can be implemented simply as an additional function in the master, which is present in any case. No additional hardware is required.

### BRIEF DESCRIPTION OF THE DRAWINGS

The invention as well as embodiments and advantages thereof will now be described in greater detail with reference to an exemplary embodiment of the invention depicted in the drawings in which:

FIG. 1 shows a network with wireless data communication between a plurality of users in accordance with the present invention; and

FIG. 2 is a timing diagram of a test cycle in accordance with the present invention.

### DETAILED DESCRIPTION OF THE PREFERRED EMBODIMENTS

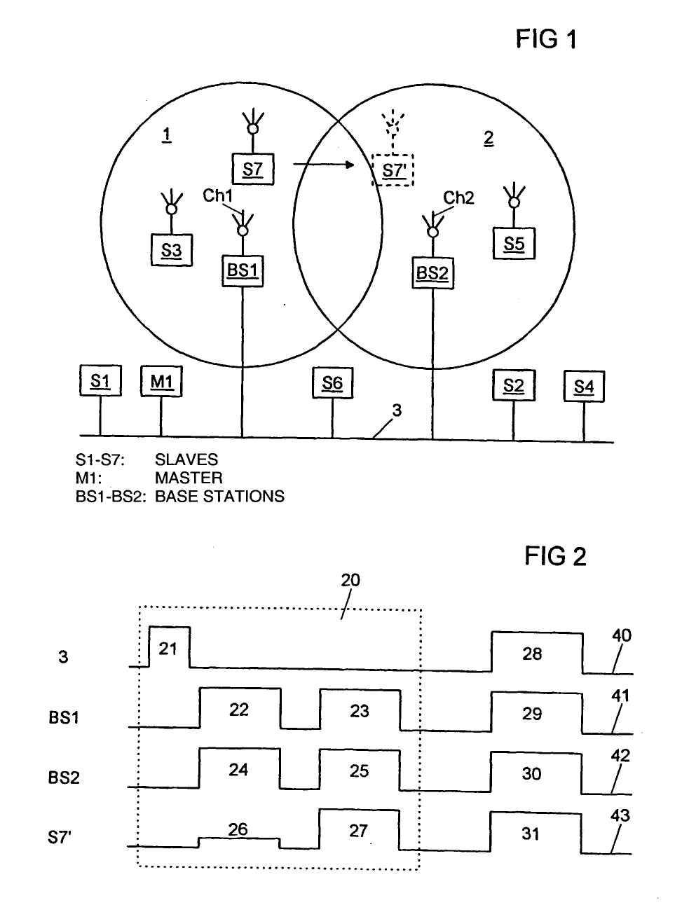

The network depicted in FIG. 1 has two radio cells 1 and 2 that are adjacent to one another and partly overlap. In each radio cell there is a base station BS1 and BS2, respectively. The base stations BS1 and BS2 are interconnected by a common communication channel 3, which is configured, for example, as a field bus based on the PROFEBUS DP standard. A stored program controller as the master M1 is connected to the field bus. In addition to its capacity as logic master, this stored program controller also performs the function of a mobility master within the PROFIBUS DP. Other users on the field bus 3 are a flow transducer as slave S1, a control valve as slave S6, a pressure transducer as slave S2 and a level transducer as slave S4. Measured values and control variables are transmitted in equidistant cycles between these field devices and the stored program controller. This type of transmission is advantageous, for example, in sampling controls. The flow transducer is used to detect an actual value, the stored program controller is used to control a manipulated variable and the control valve is used to process the data. They form a flow control device communicating via the field bus 3 in an automation system. This example illustrates that in a network used in automation technology it is of considerable advantage if the individual users of the network are granted access to the transmission medium based on a deterministic method.

In addition, three radio-coupled transport means are operated as slaves S3, S5 and S7 within the network. To illustrate the handoff procedure, FIG. 1 indicates roaming of the slave S7 from the radio cell 1 to the neighboring cell 2. At the beginning of roaming, the slave S7 is located in the cell 1, as indicated by solid lines in FIG. 1. In that cell, data is transmitted between the base station BS1 and the slave S7 via a channel Ch1. The position reached by the slave S7 in the cell 2 after roaming is indicated by dashed lines. To distinguish the two positions, the same slave is identified in that cell by the reference numeral S7′. Within the cell 2, the slave S7′ and the base station BS2 exchange data via a channel Ch2. The slave S5 also uses this same channel. The slave S3, located in the cell 1, is coupled to the base station BS1 via the channel Ch1.

The handoff procedures used during roaming from one radio cell to another will now be described in greater detail with reference to FIG. 2. A pattern 40 indicates the message traffic on the field bus 3; a pattern 41 indicates the transmission operation of the base station BS1; a pattern 42 indicates the transmission operation of the base station BS2; and a pattern 43 indicates the quality of the radio reception signal levels of the slave S7′. At a low level in the pattern 40, no messages are transmitted on the field bus 3, whereas at a high level, message traffic is present. A low level of the patterns 41 and 42 indicates that the base stations BS1 and BS2 are not sending any radio signals, whereas the high level indicates transmission activity. Finally, the pattern 43 qualitatively indicates the strength of the radio reception signal: the lower the level, the less strong the signal is.

System-compatible test cycles are inserted into the cyclic data transmission via the PROFIBUS DP. FIG. 2 shows the basic sequence of a test cycle 20. The test cycle is initiated by a message 21, which the mobility master, in this case the master M1 (FIG. 1), recurrently transmits at predefined maximum intervals to the base stations BS1 and BS2 (FIG. 1). Receipt of the message 21 prompts the base stations BS1 and BS2 to emit test signals 22, 23, 24 and 25 to the corresponding radio cells 1 and 2. Each base station sends as many test signals during a test cycle as there are communication channels for coupling mobile users in the network.

As an alternative thereto, it would be sufficient, to limit the number of emitted test signals to the total number of the communication channels used in a radio cell and the cells adjacent thereto which overlap with this cell.

To ensure that the two base stations BS1 and BS2 do not transmit simultaneously on the same communication channel, each starts sending a test signal 22 or 24 on its own communication channel Ch1 and Ch2, respectively. Thereafter, the communication channels are switched in a sequence that is uniform for all base stations in the network, and another test signal is transmitted. Thus, the test signal 22 of the base station BS1 is followed by a test signal 23 on the communication channel Ch2. In contrast, the test signal 25 of the base station BS2 is now transmitted on the communication channel Ch1. In this manner, each base station uses the communication channel of all the base stations present in the network once during a test cycle. The slave S7′ receives the test signals on the previously set communication channel Ch1, which it retains during the entire test cycle. The field strength of a reception signal 26 produced by the test signal 22 sent by the base station BS1 is smaller than the field strength of a reception signal 27 produced by the test signal 25 of the base station BS2.

The slave S7′ determines that the signals of the base station BS2 associated with the communication channel Ch2 are received with better transmission quality. Thus, the communication channel Ch2 is determined to be the channel with the best transmission properties, and the slave S7′ switches its interface for radio communication to the communication channel Ch2.

At the end of the test cycle 20, the field bus 3 is again used to transmit messages of the user data traffic. FIG. 2 shows a field bus message 28 transmitted by the base station BS1 on the communication channel Ch1 as transmission activity 29 and by the base station BS2 on the communication channel Ch2 as transmission activity 30 to the mobile users located within the corresponding radio cell. The slave S7′, which after roaming is located in the cell 2, receives the message with a reception signal 31 on the communication channel Ch2, which has the best transmission properties for the slave S7′.

As an alternative to the method depicted in FIG. 2, the base stations BS1 and BS2 can retain the respective communication channel, Ch1 and Ch2, during the test cycle, and the radio-coupled slaves S3, S5 and S7 can each switch their reception channel. This has the advantage that less time is required for transmitting the test signals within the test cycles.

Information on the characteristics of the communication channels and the time sequence of the test cycle, e.g., its start and end point, may be transmitted to the radio-coupled users together with the test signals.

In the embodiment shown, a field bus is used as the common communication channel with which the base stations are interconnected. As an alternative, the field bus itself can have a plurality of radio-linked segments. In this context, the term segment means a field bus segment with wire-bound data transmission.

The above description of the preferred embodiments has been given by way of example. From the disclosure given, those skilled in the art will not only understand the present invention and its attendant advantages, but will also find apparent various changes and modifications to the structures and methods disclosed. The applicant seeks, therefore, to cover all such changes and modifications as fall within the spirit and scope of the invention, as defined by the appended claims, and equivalents thereof.

What is claimed is:

1. A method for operating a network that includes wireless data transmission between a plurality of users, the network having at least two radio cells which at least partly overlap and in which different channels are used for data transmission, and each radio cell having at least one base station, the method comprising:
interconnecting the base stations of the at least two radio cells, respectively, via at least one common communication channel;
at predefined maximum time intervals and via the base stations, simultaneously processing test cycles of a given maximum duration, wherein test signals are transmitted from the base stations in the respective radio cells during the test cycles; and
determining, within each respective radio-coupled user and based on the test signals, the communication channel with optimum transmission properties for that radio-coupled user.

2. A method as claimed in claim 1, wherein at least one user initiates the test cycles with messages recurring at the predefined maximum time intervals.

3. A method as claimed in claim 2, wherein a user having a logic mastership in a network using an access procedure based on the master-slave principle is the user which initiates the test cycles.

4. A method as claimed in claim 1, further comprising:
sending, from each of the base stations, at least one test signal during a test cycle on the communication channel assigned to the respective base station;
setting, within each of the radio-coupled users, all the communication channels for reception of the test signals during the test cycle; and
retaining, within each respective radio-coupled user, a communication channel with the best transmission properties for the transmission of data after the test cycle.

5. A method as claimed in claim 1, wherein the base stations each successively transmit the test signals on the different communication channels during a test cycle, and no two base stations simultaneously transmit on the same communication channel.

6. A method as claimed in claim 5, further comprising:
receiving, within the radio-coupled users, the test signals during the test cycle on a communication channel that is fixed for the duration of the test cycle; and
determining which base station corresponds to the test signal on the communication channel received with the best transmission properties;
retaining, within each respective radio-coupled user, the respective communication channel of the determined base station as the one with the best transmission properties for the transmission of data after the test cycle.

7. A user device operable to communicate with various base stations within a communication network, wherein the user device is configured to determine a communication channel with the best transmission properties based on test signals transmitted by each of the base stations during test cycles and wherein further, the base stations process received data simultaneously at predefined maximum time intervals having a given maximum duration.

8. A communication system comprising:
a communication link operable to carry communication signals;
a plurality of base stations each corresponding to a respective cell and each connected to said communication link, each base station being operable to transmit test signals in each of a plurality of different channels;
a plurality of user devices each operable to receive the test signals in each channel from each base station, said user devices each comprising a channel determiner operable to determine a channel corresponding to a test signal with the strongest signal level and a switch device operable to switch an interface of the user device to the determined channel.

9. A communication system as claimed in claim 8, wherein the communication link is a PROFIBUS communication link.

10. A mobile user device for use in a wireless network made up of a plurality of area cells, the device comprising:
a receiver operable to receive a plurality of test signals transmitted simultaneously from each of a plurality of base stations, the base stations corresponding, respectively, to each area cell, wherein each test signal comprises a plurality of test messages each of which corresponds to a respective communication channel within the network.

11. A mobile user device as claimed in claim 10, wherein no two test messages corresponding to the same communication channel are transmitted at the same time.

12. A mobile user device as claimed in claim 11, further comprising a channel discriminator operable to select a particular channel corresponding to a communication channel with an optimal signal level.

13. A mobile user device as claimed in claim 10, wherein all of the test messages are transmitted during a test cycle having a fixed predetermined duration and wherein the test cycle is initiated by an initiation message generated by a master device connected to each base station through a communication link.

14. A mobile user device as claimed in claim 12, wherein communication between the user device and at least two base stations is switched from one of the base stations to another of the base stations based on the channel selection made by the user device.
